(19) United States
(12) Patent Application Publication
(10) Pub. No.: US 2019/0229030 A1
(43) Pub. Date: Jul. 25, 2019

(54) POWER MODULE AND METHOD FOR PRODUCING A POWER MODULE

(71) Applicant: Siemens Aktiengesellschaft, München (DE)

(72) Inventors: Karl Weidner, München (DE); Stefan Kiefl, München (DE)

(21) Appl. No.: 16/338,458

(22) PCT Filed: Sep. 27, 2017
(86) PCT No.: PCT/EP2017/074523

§ 371 Date: Mar. 29, 2019

(30) Foreign Application Priority Data
Sep. 30, 2016 (DE) 102016218968.9

(51) Int. Cl. H01L 23/367; H01L 23/473; H01L 21/48

(52) U.S. Cl. CPC H01L 23/367; H01L 21/4871; H01L 21/4853; H01L 23/473

(57) ABSTRACT

The invention relates to a power module and a method for producing a power module. The power module comprises a cooling body and electrical insulation and/or electrical conductor structures which are arranged thereon by means of additive manufacturing. In the method for producing a power module of said type, at least one conductor track structure is additively manufactured and at least one insulation arranged on the conductor track structure is additively manufactured.

This application is the National Stage of International Application No. PCT/EP2017/074523, filed Sep. 27, 2017, which claims the benefit of German Patent Application No. 10 2016 218 968.9, filed Sep. 30, 2016. The entire contents of these documents are hereby incorporated herein by reference.

### BACKGROUND

The present embodiments relate to a power module and a method for producing a power module.

Electronic power modules (referred to herein as power modules) for, for example, for converters, require excellent electrical and thermomechanical properties and a high electromagnetic compatibility. Increasingly more stringent demands are also placed on the robustness and service life.

### SUMMARY AND DESCRIPTION

The scope of the present invention is defined solely by the appended claims and is not affected to any degree by the statements within this summary.

The present embodiments may obviate one or more of the drawbacks or limitations in the related art. For example, a power module that is improved over the prior art is provided. For example, a higher power density, an improved service life, a compact design, and reduced inductances may be provided. As another example, a method for producing an improved power module is provided.

The power module according to one or more of the present embodiments has a conductor track structure produced by additive manufacturing and at least one insulation produced by additive manufacturing and arranged at least on the conductor track structure.

In one embodiment, the power module includes at least one power component part, on which the conductor track structure is electrically contacted.

As a consequence of improved manufacturability and on account of the newly possible geometric relationships of the power module on account of additive manufacturing, the power module according to one or more of the present embodiments has the advantages specified below.

Firstly, the power module according to one or more of the present embodiments may have a higher power density on account of the improved electrical contacting by the conductor track structure produced by additive manufacturing, which is present according to the present embodiments. A long service life of the power module according to one or more of the present embodiments may be easily achieved.

It is possible to manufacture the power module according to one or more of the present embodiments with a small volume (e.g., installation space). For example, the power module according to one or more of the present embodiments may be adapted with respect to an external form to predetermined geometric dimensions, which are predetermined, for example, by further constituent parts of larger apparatuses.

As a consequence of the broad spectrum of parts that are producible by additive manufacturing, the power module according to one or more of the present embodiments may have a multiplicity of further components that are likewise producible by additive manufacturing (e.g., passive or active electric devices). Consequently, a high degree of integration is easily achievable in the power module according to one or more of the present embodiments.

On account of additive manufacturing, the power module according to one or more of the present embodiments is manufacturable in extremely cost-effective fashion (e.g., in the case of power modules for specific tasks, which are consequently made in small quantities).

Further, the power module may have a multifunctional housing, in which further functionalities are realizable on account of the higher degree of integration. For example, a silicone encapsulation is dispensable in the power module according to one or more of the present embodiments.

Numerous novel materials that are highly insulating and high temperature resistant and, at the same time, printable may be used using additive manufacturing.

In the power module according to one or more of the present embodiments, the at least one conductor track structure may include planar conductor tracks. For example, the conductor track structure includes a flat part with planar extents and an extent in a thickness direction. The greatest and/or smallest planar extent is at least 3-times (e.g., at least ten times, at least 30 times, or at least 100 times greater than the extent in the thickness direction). The conductor tracks may form at least a portion of the flat part.

In the power module according to one or more of the present embodiments, the flat part may make up at least 50 percent, at least 80 percent, or at least 90 percent of the volume of the conductor track structure.

The inductances occurring during operation may easily be reduced on account of the planar conductor track structure.

For example, an operation of devices at temperatures of more than 200° C. is possible using the power module according to one or more of the present embodiments on account of the improved electrical contacting by the planar conductor track structure that is provided according to one or more of the present embodiments. As a consequence, Si- and/or SiC- and/or GaN-chip technologies are usable. According to one or more of the present embodiments, an improved current-carrying capacity and an improved thermal and electromechanical reliability are easily realizable.

In one embodiment, the power module is able to be embodied without solder connections and/or aluminum bond connections, as are known from the prior art. The power module according to one or more of the present embodiments need not necessarily have such electrical connections, which may break easily, and which have large dimensions. Rather, the power module according to one or more of the present embodiments is able to be embodied in robust and compact fashion.

Suitably, the power module according to one or more of the present embodiments includes a cooling body that is produced at least in part by additive manufacturing.

According to one or more of the present embodiments, cooling on both sides, for example, is easily realizable (e.g., the power module may have at least two cooling bodies, or the power component part is in thermal contact with the at least one cooling body on two sides that face away from one another).

In a development, the power module includes at least one substrate (e.g., a substrate formed with ceramics).

In one embodiment, the optionally present cooling body is linked to the at least one substrate, and/or the cooling body forms the substrate in the power module.

In one embodiment, numerous substrates for power modules that find widespread use also come into question as substrates for additive manufacturing. Thus, for example, circuit carriers may serve as substrates for additive manufacturing processes (e.g., metallized ceramics such as DCB and/or AMB and/or printed circuit boards).

Electric conductor track structures of the power module according to one or more of the present embodiments are adaptable along planar extents and in the thickness direction for integrated circuits and very different applications.

In one embodiment, further constituent parts of the power module according to one or more of the present embodiments are produced by additive manufacturing (e.g., by 3D printing). Such constituent parts may be one or more of the following components: passive and/or wireless sensors, antennas, resistors, capacitors, and inductors.

For example, active and passive electrical devices and the electrical supply lines thereof may be easily integrated into the power module according to one or more of the present embodiments by additive manufacturing (e.g., using 3D printing).

Insulations and/or conductor track structures of the power module according to one or more of the present embodiments may be embodied very finely and extremely precisely using additive manufacturing (e.g., using 3-D printing).

In the power module according to one or more of the present embodiments, the constituent parts produced by additive manufacturing are expediently manufactured by 3-D printing (e.g., stereolithography, and/or selective laser sintering and/or plasma printing and/or inkjet printing).

In the power module according to one or more of the present embodiments, the optionally present cooling body and/or the optionally present substrate and/or the conductor track structure may be formed with or by metal (e.g., with aluminum and/or copper and/or nickel and/or tin and/or gold and/or silver and/or titanium and/or palladium and/or steel and/or cobalt and/or with or by an alloy formed by one or more of the aforementioned metals and/or by additive manufacturing).

In one embodiment, the optionally present cooling body is formed with or by aluminum graphite in the power module.

In a development of the power module, the cooling body has cooling channels that are embodied for cooling fluid to flow through (e.g., for air to flow through).

In one embodiment, the power module according to one or more of the present embodiments has at least one power component part that may be formed with or by silicon and/or silicon carbide and/or gallium nitride.

In one embodiment, the at least one power component part is sintered to the conductor track structure and/or the substrate and/or the cooling body in the power module.

In one embodiment, the power module forms a power converter (e.g., an inverter or a rectifier).

A significant improvement in the thermal and electrical properties may be provided (e.g., in the case of converters). The electromagnetic compatibility may easily be improved.

In the method according to one or more of the present embodiments for producing a power module according to one or more of the present embodiments, at least one conductor track structure is produced by additive manufacturing, and/or at least one insulation that is arranged on the conductor track structure is produced by additive manufacturing.

Using the manufacturing method according to one or more of the present embodiments, it is easily possible to both quickly develop the product and introduce the product to the market and also to manufacture technology demonstrators that are similar to the product.

In one embodiment, the method includes one or more of the method acts listed below: A substrate handler/cartridge for substrates (e.g., for DCB substrates) is used with and without cooling; sintering and/or soldering paste(s) are printed with an adapted volume; devices (e.g., semiconductor devices) are fit (e.g., in precise fashion in three dimensions; the devices are connected by Ag sintering or soldering processes; structured 3-D printing of organic and/or inorganic insulating materials; structured 3-D printing of structured metallic materials (e.g., one or more conductor track structures); and the manufactured power module or corresponding constituent parts are electrically and/or optically tested.

Additive manufacturing (e.g., 3D printing) may easily facilitate an expedient, multi-layer structure and a simple integration of system components (e.g., sensors and/or logic units and/or open-loop and/or closed-loop control units and/or units that are configured and embodied for condition monitoring).

In one embodiment, the additive manufacturing is implemented by one or more of the materials listed below: metals (e.g., copper and/or nickel and/or tin and/or gold and/or silver and/or aluminum and/or titanium and/or platinum and/or palladium and/or steel and/or cobalt and/or alloys with one or more of the metals listed above); electrically and/or thermally conductive thermosets; thermally conductive and electrically conductive inks; electrically conductive pastes; electrically conductive photopolymers; electrically highly insulating and thermally conductive insulation materials; plating resist materials; and high-temperature stable and highly insulating 3D materials (e.g., PI and/or PAI and/or Peek). The 3D materials mentioned last, for example, may be easily adapted with respect to a respective coefficient of thermal expansion such that thermomechanical stresses of the power module according to one or more of the present embodiments may be reduced, and the reliability is improved.

In one embodiment, additive manufacturing using a multi-nozzle method (e.g., 3-D printing) is carried out in the method according to one or more of the present embodiments.

In one embodiment, many constituent parts of the power module that are made of different materials (e.g., polymer constituent parts and metallic constituent parts) may be manufactured in additive fashion using a single installation technique in this development (e.g., by multi-nozzle 3-D printing). In one embodiment, a multi-nozzle printing assembly line allows a mass production process with high cost-reduction potential.

In one embodiment, results obtained by simulations that are carried out in advance are taken into account in the method according to one or more of the present embodiments, and possibly occurring deviations are corrected.

### BRIEF DESCRIPTION OF THE DRAWINGS

FIG. 1 shows a schematic longitudinal section of a power module according to an embodiment produced by a method according to an embodiment; and

FIG. 2 schematically shows a flowchart of a method according to an embodiment.

### DETAILED DESCRIPTION

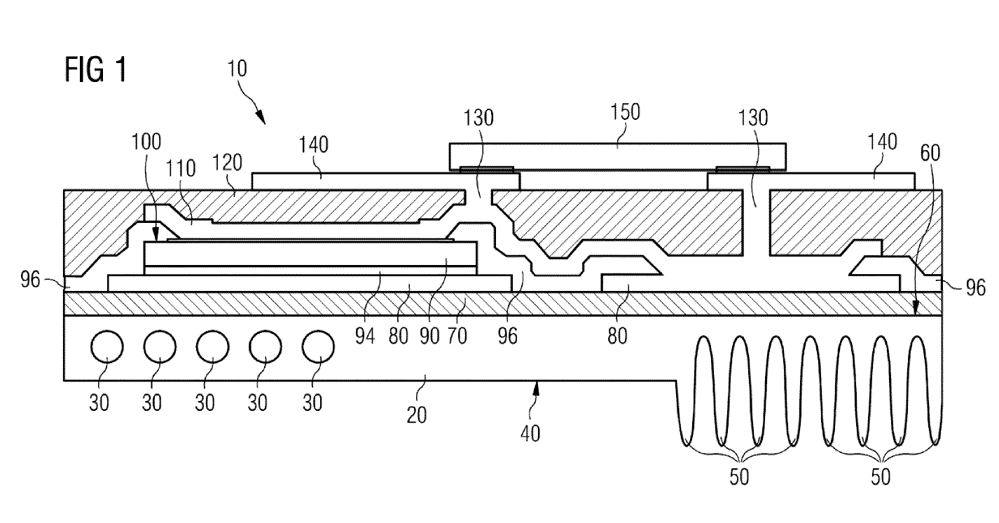

For the purposes of producing a power module 10 illustrated in FIG. 1, a cooling body 20 is initially three-dimensionally (3D) printed as a flat part of aluminum graphite. Within the scope of 3D printing of the cooling body 20, cooling channels 30 are provided in the cooling body 20 at the same time. The cooling channels 30, in the style of ducts, penetrate through the cooling body 20 in mutually parallel and equidistant fashion along the longitudinal central plane of the cooling body 20. The cooling channels 30 are embodied to pass through a liquid coolant. In principle, the cooling channels 30 are also suitable for cooling the power module with air. As an alternative to the cooling channels 30, or else in addition thereto, cooling fins 50, which protrude in perpendicular fashion from the flat side 40 of the cooling body 20, are printed onto a free flat side 40 of the cooling body 20. In the completed 3D printed part, the cooling fins 50 are dimensioned and formed in a manner known for the purposes of cooling the cooling body 20 with air.

Alternatively, in further exemplary embodiments not specifically illustrated here, the cooling body 20 is not 3D printed but manufactured by another production method and used for the further production of the power module 10 according to one or more of the present embodiments, as described below.

The flat side 60 facing away from the free flat side 40 of the cooling body 20 is embodied as a plane surface. An insulating layer 70 is printed onto this flat side 60 over the entire area thereof. In the shown exemplary embodiment, the insulating layer 70 is printed from an inorganic ceramic (e.g., aluminum nitride). In further exemplary embodiments that are not illustrated here but which otherwise correspond to what is illustrated, the insulating layer 70 is instead formed from another material (e.g., any other inorganic ceramic such as silicon nitride or an organic electric insulator). The insulating layer 70 represents a dielectric but has a high thermal conductivity. In the illustrated exemplary embodiment, the insulating layer 70 is printed onto the cooling body 20 as a thin layer. In further, not specifically illustrated exemplary embodiments, which otherwise correspond to the illustrated exemplary embodiment, the insulating layer 70 is instead sprayed or adhesively bonded onto the cooling body 20. Accordingly, the cooling body 20 forms a substrate. As an alternative or in addition thereto, a substrate may be present in place of the cooling body 20. The cooling body 20 is linked to the substrate on a side distant from the power devices 90.

A copper layer 80 with planar structuring is printed onto the insulating layer 70 as a metallization such that the insulating layer 70 with the cooling body 20 forms a substrate that is comparable to a printed circuit board. The structured copper layer 80 is equipped with power devices 90 that are embodied as flat parts (e.g., IGBTs in this case) in a manner known using silver sintering technology. The structured copper layer 80 is coated with sintering paste 94 by printing. The power devices 90 are sintered thereon. Individual structure elements of the structured copper layer 80 and the power devices 90 respectively linked thereon, together with the sintering paste 94 connecting the power device 90 and the copper layer 80 in each case, are electrically insulated from one another, respectively in a planar extent, by a further insulating layer 96, which is applied by 3-D printing. In further, not specifically illustrated exemplary embodiments, which otherwise correspond to the illustrated exemplary embodiment, silicon carbide and gallium nitride chips (e.g., integrated circuits on compound semiconductor basis) are arranged in place of IGBTs.

On flat sides 100 facing away from the cooling body 20, the power devices 90 are likewise metallized and electrically contacted by further parts of the power module 10 by copper conductor tracks 110.

Together, the copper conductor tracks 110 form a flat part (e.g., the extent of the copper conductor tracks 110 perpendicular to the flat sides 100 of the power devices 90 is smaller by one order of magnitude or two orders of magnitude than the smallest extent of the copper conductor tracks 110 in the planar directions of extent of the flat sides 100).

On respective sides facing away from the cooling body 20, both the power devices 90 and the copper conductor tracks 110 are covered by a further insulating layer 120 applied by 3D printing, and so the power devices 90 are completely embedded into the power module 10. Vias 130 are embodied by 3D printing (e.g., together with the insulating layer 120 using multi-nozzle technology) on the side of this insulating layer 120 that faces away from the cooling body 20. The vias merging into expanded contacts 140 manufactured by 3D printing and consequently contacting the expanded contacts 140 in electrically conductive fashion in embedded copper conductor tracks 110. Consequently, further, non-embedded components 150 are linked to these expanded contacts 140. In principle, the further components 150 may also be manufactured by 3-D printing. By way of example, such components 150 may be a passive and/or wireless sensor and/or an antenna and/or a resistor and/or a capacitor and/or an inductor. Further, a 3-D printed electrical supply line may be linked to the component 150.

In principle, a further insulating layer may also be printed onto the power devices 90 in further, not specifically illustrated exemplary embodiments. A further cooling body manufactured by 3-D printing is linked to the further insulating layer. Additionally, further sequences of conductor structures and insulating layers may be printed between the insulating layer and the cooling body in further exemplary embodiments.

The power module 10 according to one or more of the present embodiments, which was manufactured by the method according to one or more of the present embodiments, forms a power converter (e.g., an inverter or a rectifier).

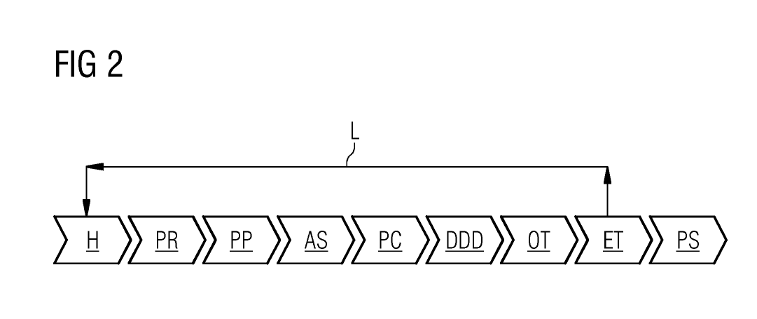

The method according to one or more of the present embodiments may be specified not only based on the specific exemplary embodiment reproduced above. Rather, the method according to one or more of the present embodiments may also be specified in general schematic fashion below, as illustrated in FIG. 2:

At the start of the method according to one or more of the present embodiments, a substrate is selected by a substrate changer H, and the substrate is transferred into the further manufacturing process. The substrate is initially handed over to a printer PR, which prints silver paste onto the substrate. Subsequently, the substrate is handed over to the equipping apparatus PP, which equips the substrate with semiconductor chips via the semiconductor chips being placed onto the silver paste. The semiconductor chips are linked to the substrate by the silver paste using a silver sintering method (AS). The semiconductor chips are pressed onto the substrate with little pressure and low temperature; this is followed by curing.

Subsequently, a structured 3D insulation (e.g., a 3D printed insulation) is applied to the semiconductor chips by a 3D printer PC with an appropriate nozzle; this is followed by a further curing act. Subsequently, a structured 3-D metal layer (e.g., a 3-D printed metal layer) is applied to the 3-D insulation by a further nozzle DDD of the 3D printer.

After 3-D printing, the power module that has been completed in this respect is initially tested in contactless fashion (e.g., tested optically in the present case; tested by an optical microscope OT). A successful optical test is followed by electrical tests on an electrical test bench (ET).

At the end of the manufacturing process illustrated in FIG. 2, packaging is implemented in a packaging station PS, as well as the further dispatch of the power module.

The method acts of 3D printing of the 3D insulation by the 3D printer PC and of 3D printing of the structured metal layer by the further nozzle DDD may also be interchanged or alternately follow one another multiple times in the method according to one or more of the present embodiments. Further, all method acts with the exception of the final packaging and dispatch using the packaging station PS may be carried out multiple times using the loop L.

The elements and features recited in the appended claims may be combined in different ways to produce new claims that likewise fall within the scope of the present invention. Thus, whereas the dependent claims appended below depend from only a single independent or dependent claim, it is to be understood that these dependent claims may, alternatively, be made to depend in the alternative from any preceding or following claim, whether independent or dependent. Such new combinations are to be understood as forming a part of the present specification.

While the present invention has been described above by reference to various embodiments, it should be understood that many changes and modifications can be made to the described embodiments. It is therefore intended that the foregoing description be regarded as illustrative rather than limiting, and that it be understood that all equivalents and/or combinations of embodiments are intended to be included in this description.

1. A power module comprising:
an additive manufactured conductor track structure; and
at least one additive manufactured insulation arranged at least on the additive manufactured conductor track structure.

2. The power module of claim 1, wherein the additive manufactured conductor track structure comprises planar conductor tracks.

3. The power module of claim 1, wherein a flat part makes up at least 50 percent of a volume of the additive manufactured conductor track structure.

4. The power module of claim 1, further comprising an at least partially additive manufactured cooling body.

5. The power module of claim 1, further comprising one or more additive manufactured constituent parts.

6. The power module of claim 4, further comprising at least one substrate.

7. The power module of claim 6, wherein the at least partially additive manufactured cooling body is linked to the at least one substrate, forms the at least one substrate, or is linked to the at least one substrate and forms the at least one substrate.

8. The power module of claim 4, wherein the at least partially additive manufactured cooling body, the at least one substrate, the additive manufactured conductor track structure, or any combination thereof is formed with or by metal.

9. The power module of claim 6, further comprising at least one power component part.

10. The power module of claim 1, further comprising one or more additive manufactured constituent parts the one or more additive manufactured constituent parts comprising a passive sensor, a wireless sensor, a passive and wireless sensor, an antenna, a resistor, a capacitor, an inductor, an electrical supply line, or any combination thereof.

11. The power module of claim 1, wherein the power module forms a power converter, the power converter being an inverter or a rectifier.

12. A method for producing a power module the method comprising:
producing at least one conductor track structure using additive manufacturing; and
arranging at least one insulation on the at least one conductor track structure, the arranging of the at least one insulation on the at least one conductor track structure comprising additive manufacturing the at least one insulation on the at least one conductor track structure.

13. The method of claim 1, wherein the additive manufacturing is carried out by a multi-nozzle method.

14. The power module of claim 3, wherein the flat part makes up at least 80 percent of the volume of the additive manufactured conductor track structure.

15. The power module of claim 14, wherein the flat part makes up at least 90 percent of the volume of the additive manufactured conductor track structure.

16. The power module of claim 5, wherein the one or more additive manufactured constituent parts comprise three-dimensionally (3D) printed constituent parts, selective laser sintered constituent parts, plasma printed constituent parts, inkjet printed constituent parts, or any combination thereof.

17. The power module of claim 16, wherein the 3D printed constituent parts comprise stereolithographed parts.

18. The power module of claim, wherein the at least one substrate comprises a ceramics substrate.

19. The power module of claim 8, wherein the metal is aluminum, copper, nickel, tin, gold, silver, titanium, palladium, steel, cobalt, an alloy, or any combination thereof.

20. The power module of claim 9, wherein the at least one power component part is sintered onto the additive manufactured conductor track structure, the at least one substrate, the at least partially additive manufactured cooling body, or any combination thereof.
